(19) United States
(12) Patent Application Publication
(10) Pub. No.: US 2022/0394863 A1
(43) Pub. Date: Dec. 8, 2022

(54) ELECTRICAL UNIT

(71) Applicant: Lear Corporation, Southfield, MI (US)

(72) Inventors: Bruce H. Pierik, Hazel Park, MI (US); Steven F. Gawron, Plymouth, MI (US)

(21) Appl. No.: 17/341,737

(22) Filed: Jun. 8, 2021

(51) Int. Cl. H05K 5/00

(52) U.S. Cl. CPC H05K 5/0052; H05K 5/0069; H05K 5/006

(57) ABSTRACT

An electrical unit housing may include a housing member, a cover, and a connector. The cover may be releasably connectable to the housing member in an assembly direction. The connector may include a latch and a tab. The latch may be disposed on the cover and the tab may be disposed on the housing member. The tab may include a first surface, a second surface, and a third surface that may extend obliquely or perpendicularly relative to each other. The second surface may extend from and connect the first surface to the third surface. The latch may be biased toward contact with the tab. The second surface may be configured to facilitate a sliding movement of the latch toward an engaged position.

### TECHNICAL FIELD

The present disclosure generally relates to electrical units, including power distribution boxes (PDBs) that may, for example, be used in connection with vehicles.

### BACKGROUND

This background description is set forth below for the purpose of providing context only. Therefore, any aspect of this background description, to the extent that it does not otherwise qualify as prior art, is neither expressly nor impliedly admitted as prior art against the instant disclosure.

Some electrical units are complex, do not provide sufficient functionality, apply unnecessary forces to certain components, and/or are difficult to assemble.

There is a desire for solutions/options that minimize or eliminate one or more challenges or shortcomings of electrical units. The foregoing discussion is intended only to illustrate examples of the present field and is not a disavowal of scope.

### SUMMARY

In embodiments, an electrical unit housing may include a housing member, a cover, and a connector. The cover may be releasably connectable to the housing member in an assembly direction. The at least one connector may include a latch and a tab. The latch may be disposed on the cover and the tab may be disposed on the housing member. The tab may include a first surface, a second surface, and a third surface that may extend obliquely or perpendicularly relative to each other. The second surface may extend from the first surface to the third surface. The second surface may connect the first surface to the third surface. The latch may be biased toward contact with the tab. The second surface may be configured to facilitate a sliding movement of the latch toward an engaged position.

In embodiments, an electrical unit housing may include a housing member, a cover releasably connectable to the housing member, and a plurality of connectors via which the housing member and the cover may be releasably connected to one another. The cover may include a formation configured to distribute at least a portion of a pressing force applied to the cover toward the plurality of connectors to facilitate connecting the cover and the housing member to one another.

In embodiments, an electrical unit housing may include a housing member, a cover, and a plurality of connectors. The cover may include a formation configured to distribute at least a portion of a force applied to the cover toward the plurality of connectors. The plurality of connectors may include a latch extending from the cover substantially in an assembly direction and a tab protruding laterally from the housing member. The tab may include a first surface, a second surface, and a third surface that may extend obliquely or perpendicularly relative to one another. The cover may be releasably connectable to the housing member via applying the force to the cover to (i) slide the latch along the first surface, (ii) flex the latch from an unengaged position toward a deflected position as the latch slides along the first surface, and (iii) dispose the latch in contact with the second surface after the latch slides beyond an end of the first surface. The second surface may be configured to bias the latch, at least to some extent, in the assembly direction. When the latch is in an engaged position, the latch may be in contact with the third surface connecting the housing member and the cover to one another.

The foregoing and other potential aspects, features, details, utilities, and/or advantages of examples/embodiments of the present disclosure will be apparent from reading the following description, and from reviewing the accompanying drawings.

### BRIEF DESCRIPTION OF THE DRAWINGS

While the claims are not limited to a specific illustration, an appreciation of various aspects may be gained through a discussion of various examples. The drawings are not necessarily to scale, and certain features may be exaggerated or hidden to better illustrate and explain an innovative aspect of an example. Further, the exemplary illustrations described herein are not exhaustive or otherwise limiting, and embodiments are not restricted to the precise form and configuration shown in the drawings or disclosed in the following detailed description. Exemplary illustrations are described in detail by referring to the drawings as follows:

FIG. 1 is a perspective view generally illustrating an embodiment of an electrical unit according to teachings of the present disclosure.

FIG. 2 is a perspective view generally illustrating an embodiment of an electrical unit housing according to teachings of the present disclosure.

FIG. 3 is a partially exploded view generally illustrating an embodiment of an electrical unit according to teachings of the present disclosure.

FIG. 4 is an exploded view generally illustrating a portion of an embodiment of an electrical unit according to teachings of the present disclosure.

FIGS. 5A-5C are a perspective view, a top-down view, and a side view, respectively, generally illustrating an embodiment of a cover according to teachings of the present disclosure.

FIG. 5D is a perspective view generally illustrating portions of an embodiment of a plurality of first latches of a cover according to teachings of the present disclosure.

FIG. 5E is a perspective view generally illustrating an embodiment of a second tab of a cover according to teachings of the present disclosure.

FIG. 5F is a cross-sectional perspective view generally illustrating portions of an embodiment of a cover with a formation according to teachings of the present disclosure.

FIGS. 6A-6C are a perspective view, a top-down view, and a side view, respectively, generally illustrating an embodiment of a housing member according to teachings of the present disclosure.

FIG. 7 is a cross-sectional view generally illustrating an embodiment of a first latch and a first tab of a first connector engaged with one another according to teachings of the present disclosure.

FIG. 8 is a cross-sectional view generally illustrating portions of an embodiment of a second latch and a second tab of a second connector engaged with one another according to teachings of the present disclosure.

FIGS. 9A and 9B are side views generally illustrating an embodiment of a method of connecting a cover and a housing member according to teachings of the present disclosure.

FIGS. 10A-10D are side views generally illustrating an embodiment of a method of engaging a first latch with a first tab according to teachings of the present disclosure.

FIGS. 11A-11D are sides views generally illustrating an embodiment of a method of disassembling a cover and a housing member (e.g., removing a cover from a housing member) according to teachings of the present disclosure.

### DETAILED DESCRIPTION

Reference will now be made in detail to embodiments of the present disclosure, examples of which are described herein and illustrated in the accompanying drawings. While the present disclosure will be described in conjunction with embodiments and/or examples, they do not limit the present disclosure to these embodiments and/or examples. On the contrary, the present disclosure covers alternatives, modifications, and equivalents.

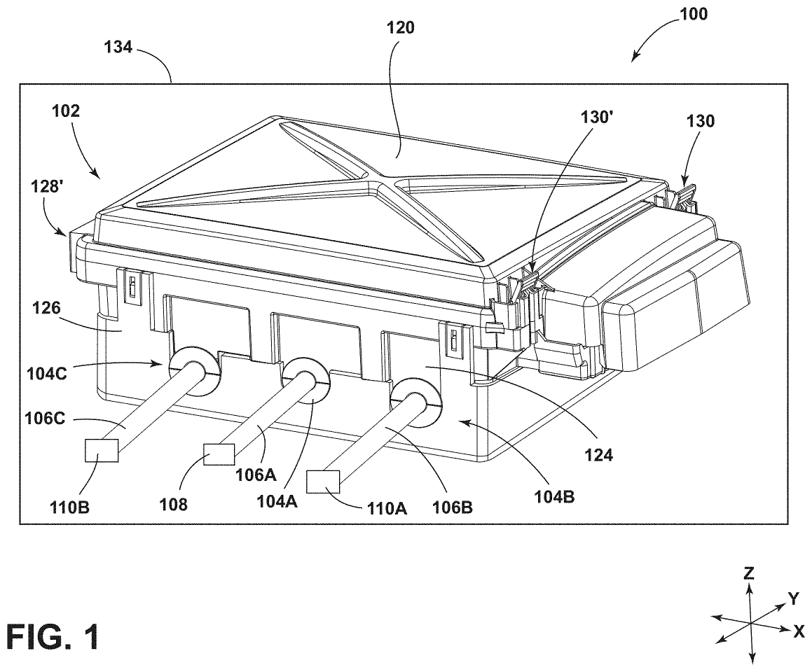

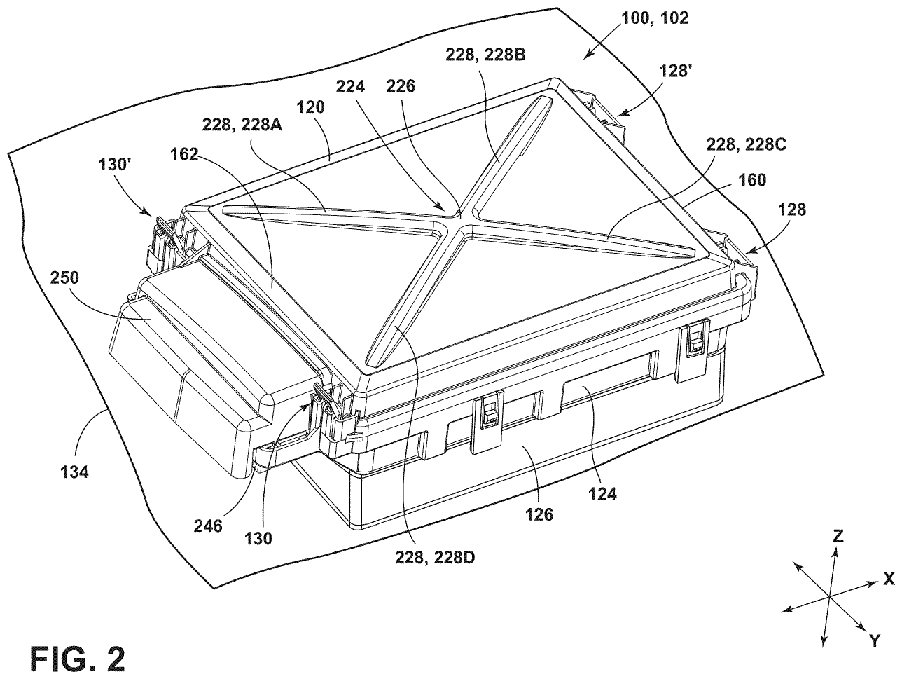

With embodiments, such as generally illustrated in FIGS. 1-3, an electrical unit 100 may include an electrical unit housing 102. An electrical unit 100 may include and/or be connected to one or more electrical connectors, such as a first electrical connector 104A, a second electrical connector 104B, and/or a third electrical connector 104C (see, e.g., FIG. 1). The first electrical connector 104A may be connected with a first cable 106A. The second electrical connector 104B may be connected with a second cable 106B. The third electrical connector 104C may be connected a third cable 106C. In embodiments, an electrical unit 100 may be configured as a power distribution unit (PDU) and/or a power distribution box (PDB). For example, the first electrical connector 104A and/or the first cable 106A may be configured to provide electrical power to the electrical unit 100, such as from a power source 108 (e.g., a battery, such as a vehicle battery). The electrical unit 100 may be configured to receive and/or distribute the electrical power to one or more other components 110A, 110B (e.g., vehicle components/systems), such as via the second electrical connector 104B and the second cable 106B, and/or via the third electrical connector 104C and the third cable 106C. A second electrical connector 104B and/or a third electrical connector 104C may, for example and without limitation, include a plurality of terminals (e.g., 30 or more) that may correspond to respective wires of cables 106A, 106B, 106C.

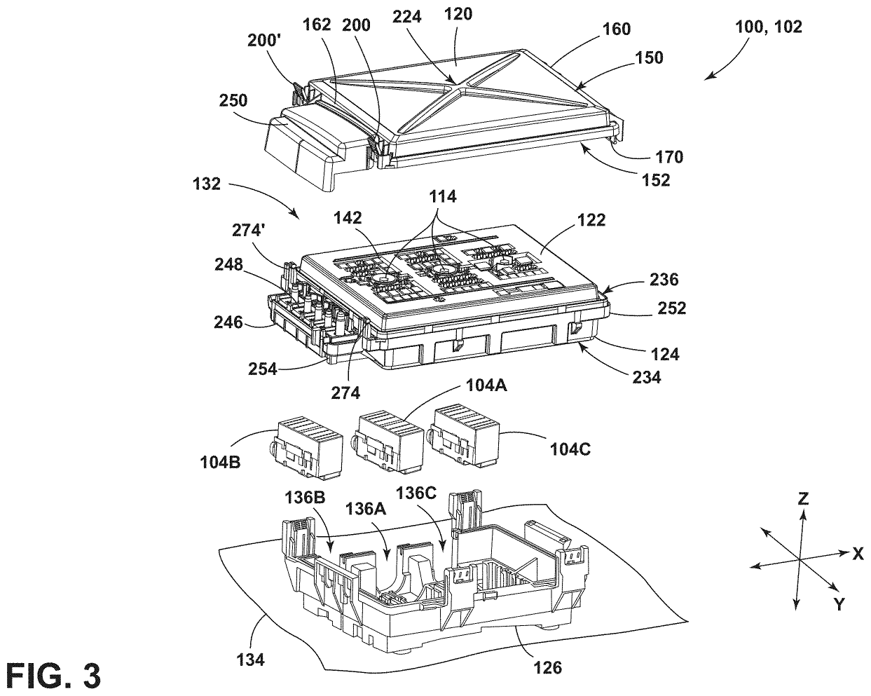

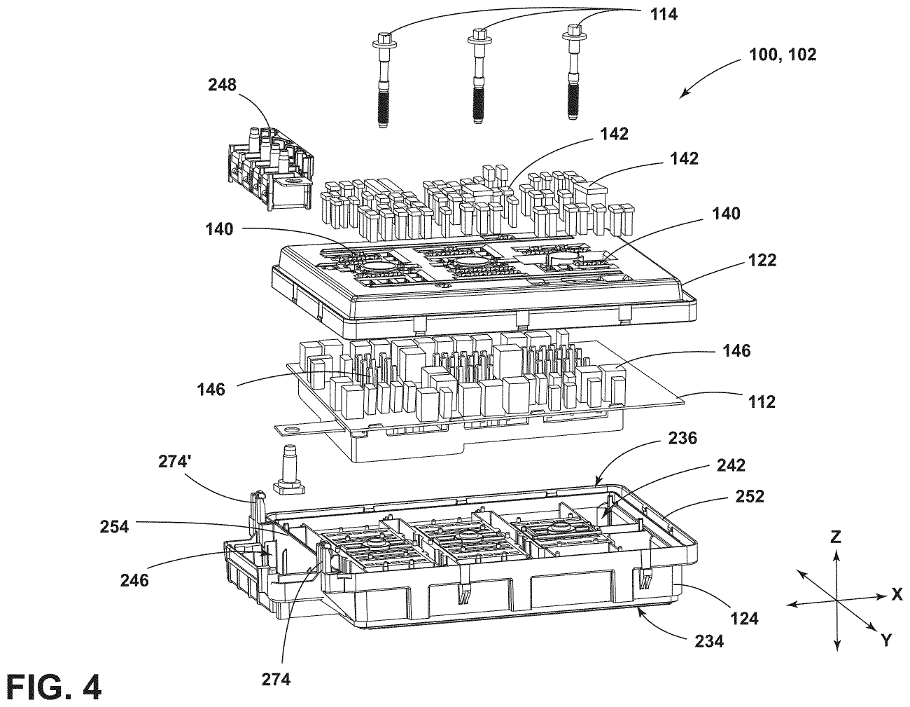

In embodiments, such as generally illustrated in FIG. 4, an electrical unit 100 may include an electrical unit housing 102, a circuit board 112, and/or one or more fasteners 114. As generally illustrated in FIG. 3, the electrical unit housing 102 may include a first cover 120, a second cover 122, a first housing member 124, a second housing member 126, one or more first connectors 128, 128′ (e.g., mechanical connectors), and/or one or more second connectors 130, 130′ (e.g., mechanical connectors). The first cover 120 may be connected to the first housing member 124, such as to define an internal space 132. The second cover 122, the circuit board 112, and/or one or more fasteners 114 may be disposed partially and/or entirely in the internal space 132. The cover 120, the second cover 122, the circuit board 112, the housing member 124, and/or the second housing member 126 may, in some configurations, be disposed in a stacked and/or overlapping configuration. For example, a second housing member 126 may be disposed on and/or connected to a mounting surface 134. The housing member 124 may disposed at least partially above/on top of the second housing member 126 (and/or one or more of the electrical connectors 104A, 104B, 104C). The circuit board 112 may be disposed at least partially above/on top of portions of the first housing member 124. The second cover 122 may be disposed at least partially above/on top of the circuit board 112 (e.g., such that the circuit board 112 is disposed substantially between the second cover 122 and the housing member 124). The cover 120 may be disposed at least partially above/on top of the second cover 122. In some configurations, the first housing member 124 may be disposed at least partially in the second housing member 126, and/or the circuit board 112 may be disposed at least partially in the first housing member 124.

In embodiments, such as generally illustrated in FIGS. 1 and 3, a second housing member 126 may include a generally rectangular configuration, among other possible configurations. In embodiments, a second housing member 126 may include a first connector recess 136A, a second connector recess 136B, and/or a third connector recess 136C that may be configured to at least partially receive the first electrical connector 104A, the second electrical connector 104B, and/or the third electrical connector 104C. For example and without limitation, the connector recesses 136A, 136B, 136C may be disposed in a first side of the second housing member 126, and a first electrical connector 104A, a second electrical connector 104B, and/or a third electrical connector 104C may be moved down such that at least bottom portions of the electrical connectors 104A, 104B, 104C are disposed in the corresponding recess 136A, 136B, 136C. With some configurations, the second housing member 126 may be referred to as a retainer and/or may be configured for mounting an electrical unit 100 on a mounting surface 134.

With embodiments, such as generally illustrated in FIGS. 3 and 4, a second cover 122 may include a generally rectangular or rectangular prism configuration (e.g., with an open bottom), among other possible configurations. A second cover 122 may include one or more apertures 140, which may, for example, be configured to at least partially receive respective a fuse or other electrical component 142 (e.g., blade fuse).

In embodiments, such as generally illustrated in FIG. 4, a circuit board 112 may, for example, include a generally rectangular configuration that may correspond to the configuration of the second cover 122 and/or the housing member 124. One or more electrical components 146 may be connected to the circuit board 112. The one or more electrical components 146 may include one or more of a variety of components, such as relays, controllers, capacitors, resistors, inductors, and/or diodes, among others. The one or more electrical components 146 may, at least in part, be configured to facilitate distribution of electrical power received via the first electrical connector 104A and/or the first cable 106A to the second electrical connector 104B, the second cable 106B, the third electrical connector 104C, and/or the third cable 106C.

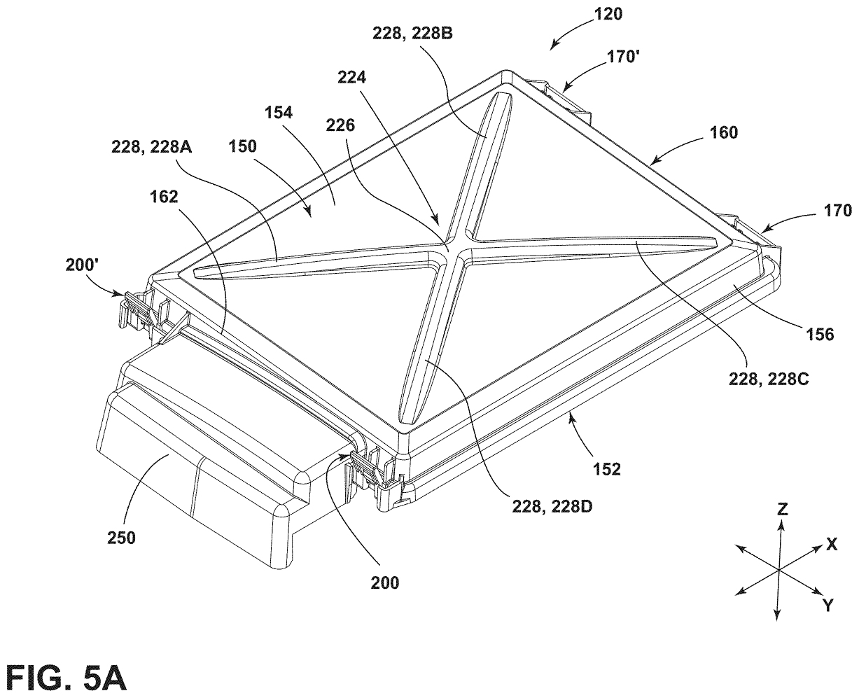

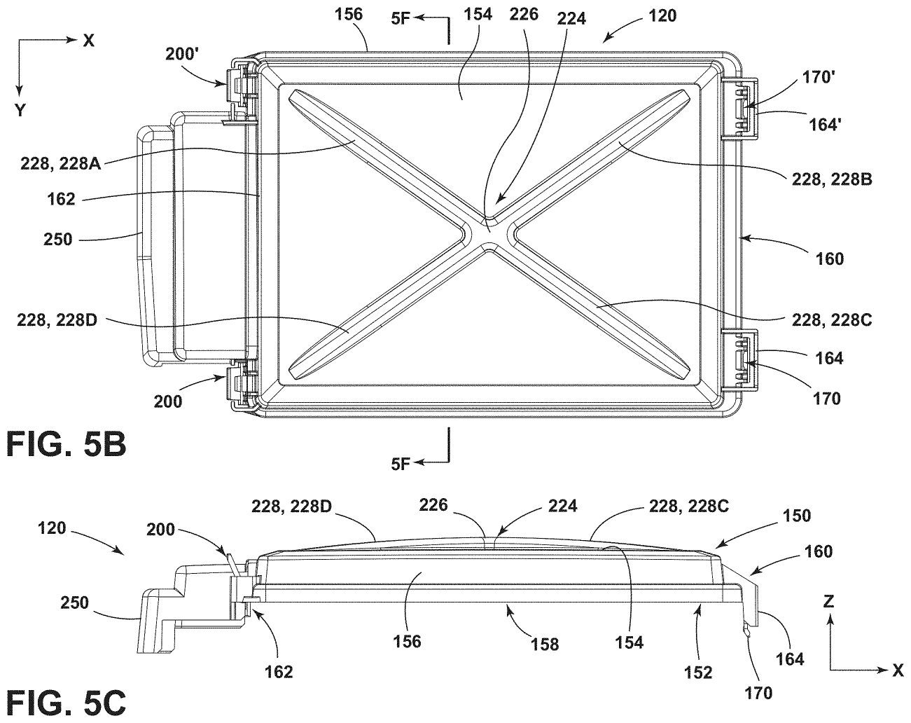

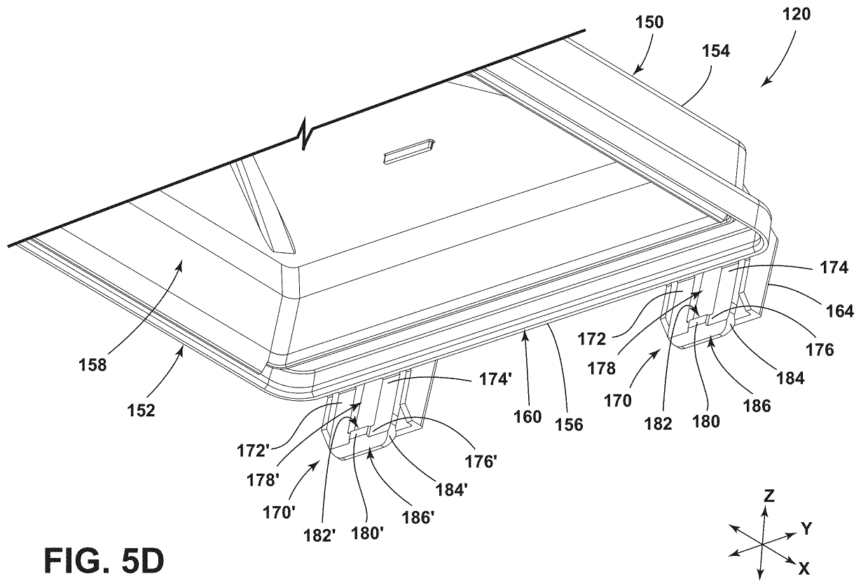

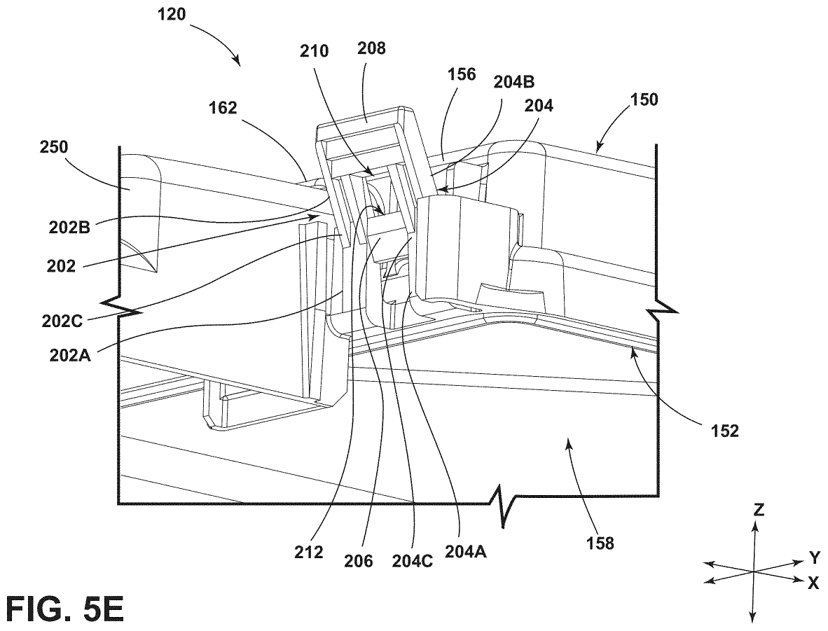

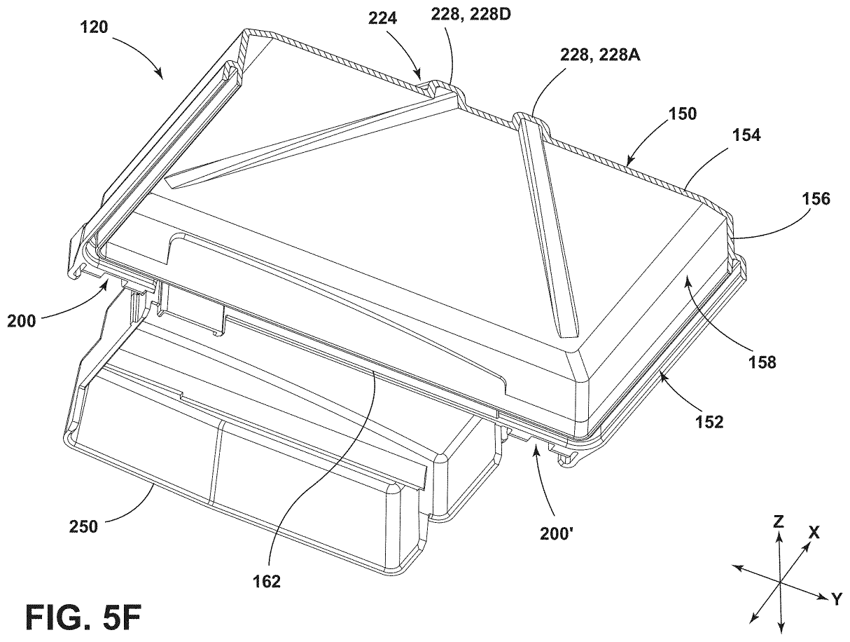

With embodiments, such as generally illustrated in FIGS. 5A-5F, a cover 120 may be releasably connectable to a housing member 124 via one or more connectors (e.g., one or more first connectors 128, 128′ and/or one or more second connectors 130, 130′). A cover 120 may include a generally rectangular or rectangular prism configuration (e.g., with an open end 152), among other possible configurations. A cover 120 may have a closed end 150 and an open end 152, which may be disposed opposite the close end 150 (e.g., relative to a Z-direction). A cover 120 may include a base portion 154 and/or one or more wall portions 156. A base portion 154 may define the closed end 150 of the cover 120 and/or may extend substantially perpendicular to a Z-direction. One or more wall portions 156 may extend from the base portion 154 generally in a Z-direction. The base portion 154 and/or one or more wall portions 156 may surround and/or at least partially define an internal space 158 of the cover 120 (see, e.g., FIGS. 5D and 5E).

With embodiments, such as generally illustrated in FIGS. 5A-5D, 7, and 9A-11D, a cover 120 may include one or more latches (e.g., one or more first latches 170, 170′), which may be part of and/or form a portion of a first connector 128. A first latch 170 may be configured to engage a first tab 260, which may be disposed on a housing member 124 for example, to releasably connect a cover 120 (e.g., a first end 160) and the housing member 124 together. A first latch 170 may extend and/or protrude from a cover 120, such as generally toward a housing member 124, away from a closed end 150 of the cover 120, and/or generally in a Z-direction. A first latch 170 may be disposed at a first end 160 of a cover 120, which may be substantially parallel to a Y-Z plane, and/or may be disposed on and/or connected to a wall portion 156 of the cover 120.

With embodiments, such as generally illustrated in FIG. 5D, a first latch 170 may include a first latch portion 172, a second latch portion 174, and/or a third latch portion 176. A first latch portion 172 and/or a second latch portion 174 may extend and/or protrude from the cover 120 (e.g., a wall portion 156), such as generally toward a housing member 124, away from a closed end 150 of the cover 120, and/or generally in a Z-direction. A first latch portion 172 and a second latch portion 174 may be substantially parallel and/or coplanar. A third latch portion 176 may extend between and/or connect a first latch portion 172 and a second latch portion 174, such as generally in a Y-direction. A first latch portion 172, a second latch portion 174, and/or a third latch portion 176 may define and/or form an opening (e.g., a latch opening 178), which may be configured to receive and/or engage at least a portion of a first tab 260. A first latch 170 may include a latching projection (e.g., a first latching projection 180) that may be configured to engage a first tab 260. A first latching projection 180 may extend, protrude, and/or project from a third latch portion 176 (e.g., toward an internal space 158 of the cover 120; generally in an X-direction) and/or may border a latch opening 178 of the first latch 170. A first latching projection 180 and/or a third latch portion 176 may include and/or collectively define a projection surface (e.g., a first projection surface 182), which may be configured to engage, contact, and/or abut a first tab 260 (e.g., a third surface 266). A first projection surface 182 of the latching projection 180 may face generally toward the closed end 150 of the cover 120 (e.g., may be generally parallel to an X-Y plane) and/or may at least partially define the latch opening 178.

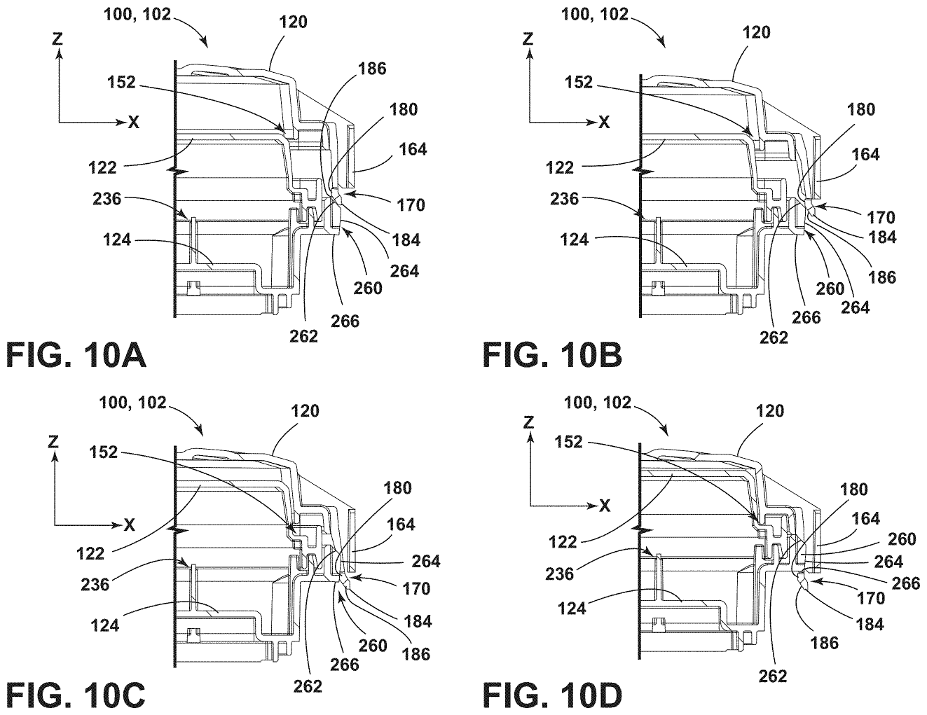

With embodiments, such as generally illustrated in FIG. 5D, a first latch 170 may include an angled latch portion 184, which may be connected to and/or extend from a third latch portion 176. An angled latch portion 184 may extend obliquely or perpendicularly relative to a first latch portion 172, a second latch portion 174, a third latch portion 176, and/or an assembly direction (e.g., a Z-direction). An angled latch portion 184 may include a first sliding surface 186 that may be configured to face generally toward a first surface 262 of a first tab 260. A first sliding surface 186 may extend and/or be sloped in a similar manner to a first surface 262 of a first tab 260 such that, for example, an angle defined between the first sliding surface 186 and the first surface 262 is smaller than an angle defined between the first sliding surface 186 and a first latch portion 172, a second latch portion 174, and/or a third latch portion 176 (see, e.g., FIG. 10A), which may facilitate engaging the first latch 170 with the first tab 260, sliding of the first latch 170 along the first surface 262 of the first tab 260, and/or adjusting, deflecting, flexing, etc. of the first latch 170 toward a deflected position. An angled latch portion 184 may additionally and/or alternatively facilitate disengaging of a first latch 170 from a first tab 260 and/or removing a cover 120 from a housing member 124, such as by providing an easily accessible and/or actuatable portion via which a user may deform and/or flex the first latch 170 to disengage the first latch 170 from the first tab 260.

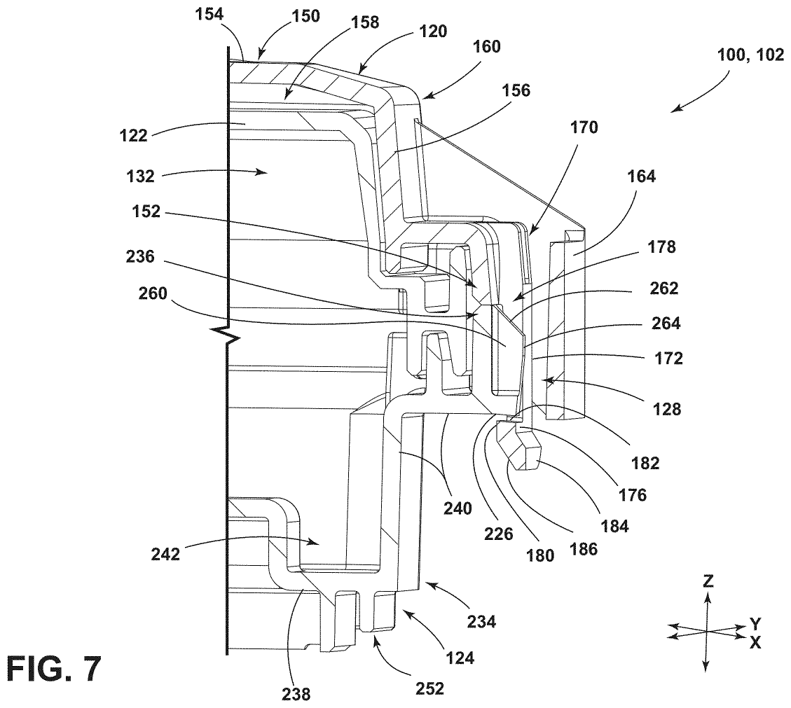

With embodiments, such as generally illustrated in FIGS. 10A-10D, a first latch 170 may be configured to elastically deform, flex, and/or deflect, such as generally in an X-direction, when engaging and/or disengaging a first tab 260. A first latch 170 may be adjustable, elastically deformable, flexible, and/or deflectable toward and/or to an unengaged position (see, e.g., FIGS. 5C, 5D, 9A, 10A, 11C, 11D), a deflected position (see, e.g., FIGS. 10B, 10C), and/or an engaged position (see, e.g., FIGS. 7, 9B, 10D, 11A, 11B). A first latch 170 may be disposed in an unengaged position when a cover 120 and a housing member 124 are not connected to one another and/or when the first latch 170 is in contact with but not engaged with a first tab 260. A first latch 170 may be disposed in an engaged position when a cover 120 and a housing member 124 are connected to one another and/or when the first latch 170 is engaged with a first tab 260 (e.g., when a first projection surface 182 of the first latch 170 is in contact with a third surface 266 of the first tab 260). When in an unengaged position and/or when in an engaged position, a first latch 170 may not be elastically deformed, flexed, and/or deflected (e.g., generally in an X-direction). For example, in some configurations, the first latch 170 may be disposed in substantially the same position relative to the rest of the cover 120 in the engaged and unengaged positions. A first latch 170 may be adjusted toward a deflected position (e.g., from an unengaged position and/or from an engaged position), such as when connecting and/or disconnecting a cover 120 and a housing member 124 from one another. When in a deflected position, a first latch 170 may be elastically deformed, flexed, and/or deflected (e.g., generally in an X-direction), and/or may be biased towards an unengaged position and/or an engaged position. A first latch 170 may, additionally and/or alternatively, contact, press against, and/or be biased against a first tab 260 (e.g., a first surface 262 and/or a second surface 264), which may facilitate sliding of the first latch 170 along a second surface 264 of the first tab 260 toward an engaged position of the first latch 170 and/or may reduce an amount of force (at least to some extent) that a user may apply to the cover 120 and/or the housing member 124 to engage the first latch 170 and the first tab 260, which may in turn facilitate connecting the cover 120 and the housing member 124 together.

With embodiments, such as generally illustrated in FIG. 5D, a cover 120 may include a first latch 170 and another/additional first latch 170′, which may be disposed at or about opposite sides of the first end 160 of the cover 120 such that each of the first latches 170, 170′ are disposed at or about a corner of the electrical unit housing 102. A first latch 170′ may be configured to engage a first tab 260′ and/or may be configured in a similar and/or same manner as a first latch 170. A first latch 170′ may include a first latch portion 172′, a second latch portion 174′, a third latch portion 176′, a latch opening 178′, a first latching projection 180′, a projection surface 182′, an angled latch portion 184′, and/or a first sliding surface 186′, which may be configured in a similar and/or same manner as the corresponding feature of a first latch 170.

With embodiments, such as generally illustrated in FIGS. 5D and 7, a cover 120 may include one or more guard/shield portions 164, which may be configured to protect at least a portion of a first connector 128 and/or to restrict flexing/movement of a first latch 170 at least to some extent. A guard portion 164 may extend and/or protrude from a cover 120 (e.g., from a wall portion 154 of the cover 120), such as generally toward a housing member 124, away from a closed end 150 of the cover 120, and/or generally in a Z-direction. A guard portion 164 may extend generally parallel to a first latch 170 (e.g., a first latch portion 172 and/or a second latch portion 174) and/or be disposed spaced apart from a first latch 170 such as generally in an X-direction, which may allow the first latch 170 to come into contact with the guard portion 164, such as when it is adjusted, flexed, deflected, etc. during connection of the cover 120 and the housing member 124, to restrict and/or prevent further adjusting, flexing, deflecting, etc. of the first latch 170. In this manner, for example, a maximum distance a first latch 170 may be adjusted, deformed, flexed, and/or deflected (e.g., generally in an X-direction) may be set and/or limited via a guard portion 164. A guard portion 164 may for example, include a generally U-shaped configuration that may open inward toward a center of an electrical unit 100 (e.g., in an X-direction). A cover 120 may include a guard portion 164 for some or each latch, such as a first guard portion 164 for a first latch 170 and/or another/additional guard portion 164′ for another/additional first latch 170′. A guard portion 164′ may be configured in a similar and/or the same manner as a guard portion 164.

With embodiments, such as generally illustrated in FIGS. 5A-5C, 5E, 8, 9A, 9B, and 11A-11D, a cover 120 may include one or more tabs (e.g., one or more second tabs 200, 200′), which may be part of and/or form a portion of a second connector 130. A second tab 200 may be configured to engage a second latch 274, which may be disposed on a housing member 124 for example, to releasably connect the cover 120 (e.g., a second end 162) and the housing member 124 together. A second tab 200 may be disposed at a second end 162 of the cover 120 (e.g., on a wall portion 156 of the cover 120), which may be generally parallel with an Y-Z plane and/or may be disposed opposite the first end 160 of the cover 120.

With embodiments, such as generally illustrated in FIG. 5E, a second tab 200 may include a first tab portion 202, a second tab portion 204, a third tab portion 206, and/or a fourth tab portion 208 (e.g., an actuation portion). A first tab portion 202, a second tab portion 204, a third tab portion 206, and/or a fourth tab portion 208 may define and/or form an opening (e.g., a tab opening 210), which may be configured to receive and/or engage at least a portion of a second latch 274 (e.g., at least a portion of a second latching projection 276). A third tab portion 206 may be configured to engage and/or contact a second latch 274 and/or one or more surfaces thereof (e.g., a second sliding surface 280 and/or a second projection surface 278). A third tab portion 206 may include a tab surface 212, which may be configured to engage, contact, and/or abut a second latch 274 (e.g., a second projection surface 278 of the second latch 274). A tab surface 212 may face generally away from the housing member 124, toward the closed end 150 of the cover 120, and/or generally upward in a Z-direction. A fourth tab portion 208 may be configured to facilitate disengaging of a second latch 274 and a second tab 200 and/or removing a cover 120 from a housing member 124, such as by providing an easily accessible and/or actuatable portion via which a user may move, deform, and/or flex the second tab 200 to disengage the second latch 274 from the second tab 200.

With embodiments, such as generally illustrated in FIG. 5E, a first tab portion 202 and/or a second tab portion 204 may extend and/or protrude from the cover 120 (e.g., a wall portion 156), such as generally away from a housing member 124, toward a closed end 150 of the cover 120, and/or generally upward in a Z-direction (and/or an angle, such as an acute angle, relative thereto). A first tab portion 202 and a second tab portion 204 may be substantially parallel and/or coplanar. In at least some examples, a first tab portion 202 and/or a second tab portion 204 may be bent, angled, and/or curved such that, for example, the third tab portion 206 and the fourth tab portion 208 are disposed offset from one another relative to a Z-direction and/or an X-direction. A first tab portion 202 and/or a second tab portion 204 may, for example, include a first section 202A, 204A and/or a second section 202B, 204B that may be connected to one another at a transition region 202C, 204C. A first section 202A, 204A may be connected to and/or extend from a cover 120. A second section 202B, 204B may extend obliquely or perpendicularly from a free/distal end of a first section 202A, 204A. A third tab portion 206 and/or a fourth tab portion 208 may extend between and/or connect a first tab portion 202 and a second tab portion 204, such as generally in a Y-direction, and/or may be disposed spaced apart from one another. A third tab portion 206 may extend between and/or be connected to a transition region 202C of a first tab portion 202 and/or a transition region 204C of a second tab portion 204. A fourth tab portion 208 may extend between and/or be connected to a free/distal end of a first tab portion 202 (e.g., an end not directly connected to the cover 120) and/or a free/distal end of a second tab portion 204 (e.g., an end not directly connected to the cover 120).

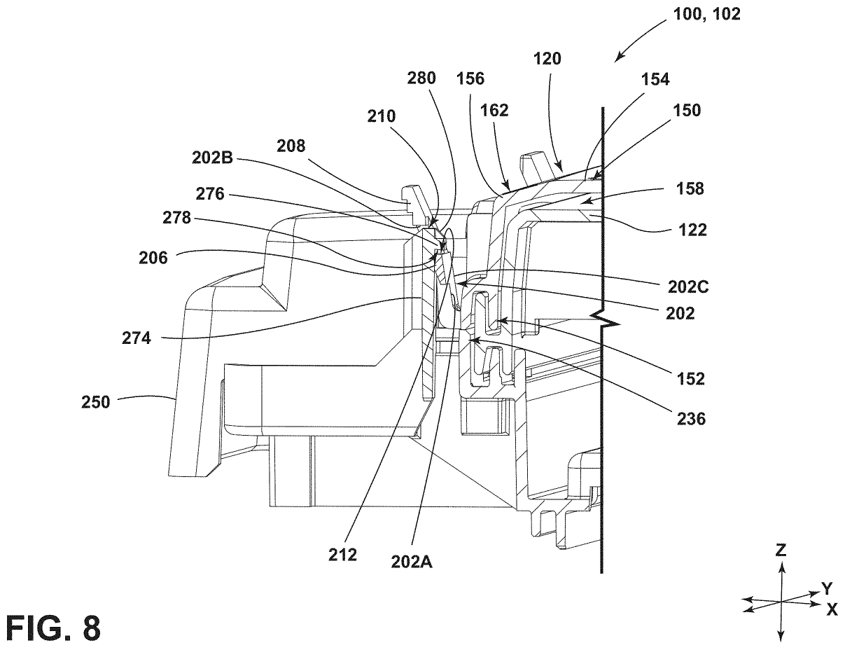

With embodiments, such as generally illustrated in FIGS. 5C, 5E, and 8, a second tab 200 and/or one or more portions thereof (e.g., a first tab portion 202 and/or a second tab portion 204) may be configured to elastically deform, flex, and/or deflect, such as generally in an X-direction, when engaging and/or disengaging a second latch 274. A second tab 200 may be adjustable, elastically deformable, flexible, and/or deflectable toward and/or to an unengaged position (see, e.g., FIGS. 5C, 5E, 9A, 11B-11D), a deflected position, and/or an engaged position (see, e.g., FIGS. 8, 9B, 11A). A second tab 200 may be disposed in an unengaged position when a cover 120 and a housing member 124 are not connected to one another and/or when the second tab 200 is in contact with but not engaged with a second latch 274. A second tab 200 may be disposed in an engaged position when a cover 120 and a housing member 124 are connected to one another and/or when the second tab 200 is engaged with a second latch 274 (e.g., when a tab surface 212 of the second tab 200 is in contact with a second projection surface 278 of a second latch 274). When in an unengaged position and/or when in an engaged position, a second tab 200 may not be elastically deformed, flexed, and/or deflected (e.g., generally in an X-direction). For example, in some configurations, the second tab 200 may be in substantially the same position relative to the cover 120 in the unengaged and engaged positions. A second tab 200 may be adjusted toward a deflected position (e.g., from an unengaged position and/or from an engaged position) when connecting and/or disconnecting a cover 120 and a housing member 124 from one another. When in a deflected position, a second tab 200 may be adjusted, elastically deformed, flexed, and/or deflected (e.g., generally in an X-direction), and/or may be biased towards an unengaged position and/or an engaged position.

As generally shown in FIG. 5A, a cover 120 may include a second tab 200 and another second tab 200′, which may be disposed at or about opposite sides of the second end 162 of the cover 120 such that each of the second tabs 200, 200′ are disposed at or about a corner of the electrical unit housing 102. A second tab 200′ may be configured to engage a second latch 274′ and/or may be configured in a similar and/or same manner as a second tab 200. A second tab 200′ may include a first tab portion, a second tab portion, a third tab portion, a fourth tab portion, a tab opening, a tab surface, a first section, a second section, and/or a transition region, which may be configured in a similar and/or same manner as the corresponding feature of a second tab 200.

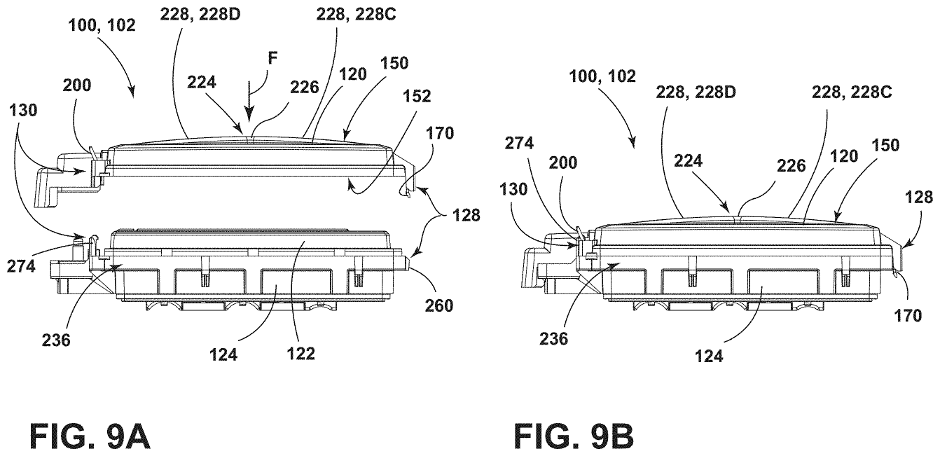

With embodiments, such as generally illustrated in FIGS. 5A-5C and 5F, a cover 120 may include one or more formations 224, which may be configured to distribute a force F (e.g., a pressing force; see, e.g., FIG. 9A) applied to the cover 120, such as when connecting the cover 120 to the housing member 124. A formation 224 may be configured to distribute a force F applied to a cover 120 (e.g., to the formation 224) toward one or more connectors (e.g., one or more first connectors 128, 128′ and/or one or more second connectors 130, 130′). A formation 224 may be configured such that, for example, the force F is substantially concentrated at or about the connectors 128, 128′, 130, 130′ and/or the force F is distributed substantially evenly among the one or more connectors 128, 128′, 130, 130′. Distributing a force F applied to a cover 120 to a connector 128, 128′, 130, 130′ via a formation 224 may facilitate connecting the cover 120 to a housing member 124. For example, distributing a force F applied to a cover 120 to a connector 128, 128′, 130, 130′ via a formation 224 may allow a user to engage one or more portions of the connector 128, 128′, 130, 130′ (e.g., a first latch 170 and a first tab 260, a second latch 274 and a second tab 200, etc.) with a single application of force (e.g., applied at or about main portion 226), which may make the process of connecting a cover 120 to a housing member 124 easier and/or more convenient for the user. Additionally and/or alternatively, the formation 224 may reduce a minimum amount of force a user needs to apply to connect a cover 120 to a housing member 124 since a greater portion of the applied force F is applied to and/or is concentrated at or about the connectors 128, 128′, 130, 130′. For example, the formation 224 may be configured to allow for connection/engagement of some or all connectors 128, 128′, 130, 130′ with a user applying force proximate the main portion 226 and without the user directly applying force proximate the connectors 128, 128′, 130, 130′.

With embodiments, such as generally illustrated in FIGS. 5A-5C and 5F, a formation 224 may project from a cover 120 (e.g., from a base portion 154 of a cover 120), such as generally upward in a Z-direction. A formation 224 may be disposed on, integrally formed with, and/or connected to a cover 120 (e.g., via a mechanical connection, an adhesive connection, etc.). For example, a formation 224 may be configured as a stamped-in portion and/or a molded portion of a cover 120, such as generally illustrated in FIG. 5F. A formation 224 may or may not be completely hollow and/or partially hollow.

With embodiments, such as generally illustrated in FIGS. 5A-5C, a formation 224 may include a main portion 226 and/or one or more ribs 228 (e.g., four ribs 228A, 228B, 228C, 228D). A main portion 226 may be disposed at or about a center of a cover 120 (e.g., a base portion 154). A formation 224 may, in other examples, include several main portions 226 that may be disposed spaced apart from one another. In some embodiments, a main portion 226 may be disposed at a point where a plurality of ribs 228 intersect one another. Additionally and/or alternatively, a main portion 226 may be formed and/or defined by intersecting portions of a plurality of ribs 228.

With embodiments, such as generally illustrated in FIGS. 5A-5C and 5F, a rib 228 may have a substantially rectangular cross-section and/or may extend toward one or more connectors 128, 128′, 130, 130′. A rib 228 may, however, have a cross-section with other desired shapes (e.g., square, triangle, oval, circle, etc.). In some examples, the number of ribs 228 may correspond to and/or match the number of connectors 128, 128′, 130, 130′, and/or each rib 228 may extend toward an associated connector 128, 128′, 130, 130′. A rib 228 may contact and/or extend from a main portion 226. Additionally and/or alternatively, a rib 228 may protrude and/or branch out from another rib 228. A plurality of ribs 228 may project radially outward from a main portion 226 such that the formation 224 has a hub-and-spoke configuration when viewed in a Z-direction. For example, as generally illustrated in FIG. 5A, a substantially rectangular cover 120 with connectors 128, 128′, 130, 130′ disposed at its vertices/corners may have an X-shaped formation 224 with four ribs 228A, 228B, 228C, 228D extending from a main portion 226. In another example, a substantially hexagonal cover 120 with connectors 128, 130 disposed at its vertices/corners may have an asterisk-shaped formation 224 (e.g., a *-shaped formation 224) with six ribs 228 extending from a main portion 226.

With embodiments, such as generally illustrated in FIGS. 5A, 5C, and 5F, a height of a formation 224 (e.g., a distance the formation 224 extends from the cover 120 and/or the base portion 154 generally upward in a Z-direction) may be greatest at or about a main portion 226 and/or may decrease along a length of one or more (e.g., all) ribs 228 in a direction away from the main portion 226. A height of a formation 224 may exponentially decrease in a direction away from a main portion 226 such that, for example, the formation 224 has a dome-like profile when viewed in an X-direction and/or a Y-direction (e.g., ribs 228 may be curved, at least to some degree). Additionally and/or alternatively, a height of a formation 224 may linearly decrease away from a main portion 226 such that, for example, the formation 224 has a cone-like profile and/or a truncated cone-like profile when viewed in an X-direction and/or a Y-direction.

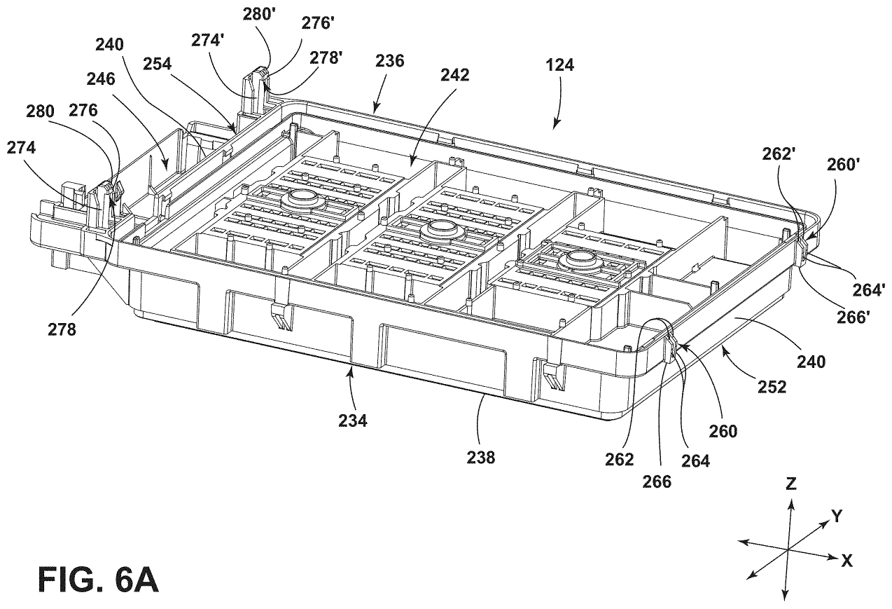

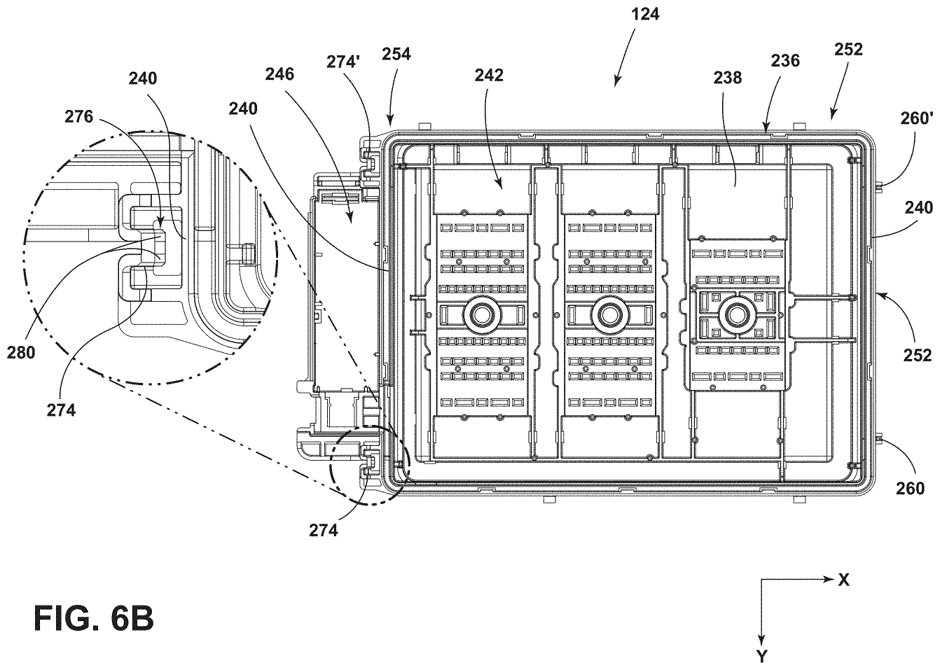

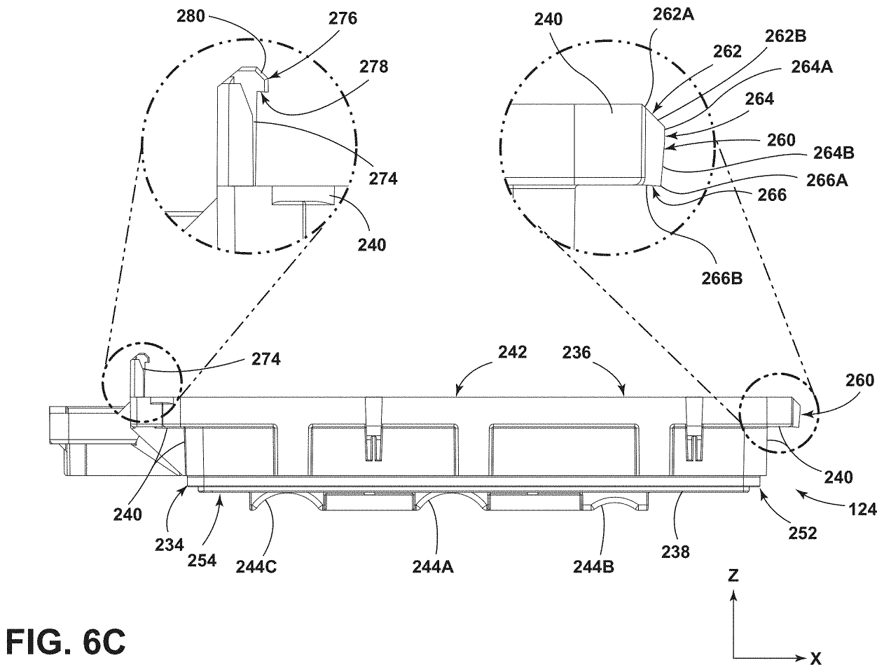

In embodiments, such as generally illustrated in FIGS. 4 and 6A-6C, a housing member 124 may be releasably connectable to a cover 120 via one or more connectors (e.g., one or more first connectors 128, 128′ and/or one or more second connectors 130, 130′). A housing member 124 may additionally and/or alternatively be releasably connectable to a second cover 122, such as to enclose a circuit board 112. A housing member 124 may include a generally rectangular configuration, among other possible configurations. A housing member 124 may have a closed end 234 and an open end 236, which may be disposed opposite the closed end 234 (e.g., relative to a Z-direction). A housing member 124 may include a base portion 238 and/or one or more wall portions 240. A base portion 238 may define the closed end 234 of the housing member 124 and/or may extend substantially perpendicular to a Z-direction. One or more wall portions 240 may extend from the base portion 238 generally in a Z-direction. The base portion 238 and/or one or more wall portions 240 may surround and/or at least partially define an internal space 242 of the housing member 124.

As generally illustrated in FIG. 6C, a housing member 124 may include a first connector recess 244A, a second connector recess 244B, and/or a third connector recess 244C that may be configured to at least partially receive a first electrical connector 104A, a second electrical connector 104B, and/or a third electrical connector 104C. For example and without limitation, the base portion 238 of the housing member 124 may include the connector recesses 244A, 244B, 244C, which may be disposed outside of the internal space 242 of the housing member 124. The housing member 124 may be disposed (e.g., moved down) over a first electrical connector 104A, a second electrical connector 104B, and/or a third electrical connector 104C such that top portions of the electrical connectors 104A, 104B, 104C are disposed in the recesses 244A, 244B, 244C. Additionally and/or alternatively, a housing member 124 may include an assembly receptacle 246, which may be configured to at least partially receive and/or retain a hybrid-frequency cascaded full-bridge (HCFB) assembly 248 and/or which may be closed/covered by an extension 250 of the cover 120 (see, e.g., FIGS. 3 and 4).

With embodiments, such as generally illustrated in FIGS. 6A-7, a housing member 124 may include one or more tabs (e.g., one or more first tabs 260, 260′), which may be part of and/or form a portion of a first connector 128. A first tab 260 may be configured to engage a first latch 170, such as to releasably connect the cover 120 (e.g., a first end 160) and the housing member 124 together. A first tab 260 may extend and/or protrude from a housing member 124 (e.g., generally in a X-direction), such as outwardly from a wall portion 240 of a housing member 124 and/or inwardly from a wall portion 240 of a housing member 124. A first tab 260 may be disposed at a first end 252 of a housing member 124, which may be generally parallel to Y-Z plane.

With embodiments, such as generally illustrated in FIGS. 6C, 7, and 10A-10D, a first tab 260 may include a first surface 262 (e.g., an outwardly sloped surface), a second surface 264 (e.g., an inwardly sloped surface), and/or a third surface 266 (e.g., an engagement surface). A first surface 262, a second surface 264, and/or a third surface 266 may extend obliquely or perpendicularly relative to one another. Additionally and/or alternatively, a first surface 262, a second surface 264, and/or a third surface 266 may extend obliquely relative to an X-direction and/or a Z-direction.

With embodiments, such as generally illustrated in FIG. 6C, a first surface 262 of a first tab 260 may be configured to guide a first latch 170 toward a second surface 264 of the first tab 260, and/or may be configured to adjust, elastically deform, flex, and/or deflect the first latch 170 (e.g., toward a deflected position) as the first latch 170 slides along the first surface 262 toward the second surface 264. A first surface 262 of a first tab 260 may be sloped away from an open end 236 of a housing member 124 and/or away from a wall portion 240 of the housing member 124 to which the first tab 260 may be connected. A first end 262A of a first surface 262 may contact and/or extend from a wall portion 240 of a housing member 124. A second end 262B of a first surface 262 may contact and/or abut a first end 264A of a second surface 264. A second end 262B of a first surface 262 may be disposed farther from an open end 236 of a housing member 124 (e.g., be at a lower level) than a first end 262A of the first surface 262 relative to a Z-direction.

With embodiments, such as generally illustrated in FIG. 6C, a second surface 264 of a first tab 260 may be configured to bias/guide a first latch 170 toward a third surface 266 of the first tab 260 (e.g., toward an engaged position), and/or may contact the first latch 170 to facilitate (e.g., bias, guide, etc.) sliding of the first latch 170 along the second surface 264 toward the third surface 266, which may facilitate engaging the first latch 170 and the first tab 260 with one another. A second surface 264 of a first tab 260 may be sloped back/inward toward a wall portion 240 of the housing member 124 from which the first tab 260 extends. A first end 264A of a second surface 264 may contact and/or abut a second end 262B of a first surface 262. A second end 264B of a second surface 264 may contact and/or abut a first end 266A of a third surface 266. A first end 264A of a second surface 264 may be disposed farther from a wall portion 240 of a housing member 124 to which the first tab 260 is connected than a second end 264B of the second surface 264 relative to an X-direction.

With embodiments, such as generally illustrated in FIG. 6C, a third surface 266 of a first tab 260 may be configured to engage, contact, and/or abut a surface of a first latch 170 (e.g., a first projection surface 182). A third surface 266 of a first tab 260 may be sloped back/upward toward an open end 236 of a housing member 124 and/or may be sloped back toward a wall portion 240 of the housing member 124 to which the first tab 260 is connected. A first end 266A of a third surface 266 may contact and/or abut a second end 264B of a second surface 264. A second end 266B of a third surface 266 may contact and/or extend from a wall portion 240 of a housing member 124. A first end 266A of a third surface 266 may be disposed farther from an open end 236 of a housing member 124 than a second end 266B of the third surface 266 relative to a Z-direction. A second end 262B of the first surface 262 may be disposed farther from a wall portion 240 of the housing member 124, from which the first tab 260 may extend, than a second end 264B of the second surface 264 and/or a first end 266A of a third surface 266.

With embodiments, such as generally illustrated in FIG. 6A, a housing member 124 may include a first tab 260 and another first tab 260′, which may be disposed at or about opposite ends of the first end 252 of the housing member 124 such that each of the first tabs 260, 260′ are disposed at or about a corner of the electrical unit housing 102. A first tab 260′ may be configured to engage a first latch 170′ and/or may be configured in a similar and/or same manner as a first tab 260. A first tab 260′ may include a first surface 262′, a second surface 264′, and/or a third surface 266′, which may be configured in a similar and/or the same manner as the corresponding feature of a first tab 260.

With embodiments, such as generally illustrated in FIGS. 6A-6C and 8, a housing member 124 may include one or more latches (e.g., one or more second latches 274), which may be part of and/or form a portion of a second connector 130. A second latch 274 may be configured to engage a second tab 200, such as to releasably connect a second end 162 of a cover 120 and the housing member 124 together. A second latch 274 may extend and/or protrude from a housing member 124, such as generally toward a cover 120, away from a closed end of the housing member 124, and/or generally upward in a Z-direction. A second latch 274 may be disposed at a second end of a housing member 124, which may be generally parallel to a Y-Z plane and/or may be disposed opposite the first end of the housing member 124.

With embodiments, such as generally illustrated in FIGS. 6A, 6C, and 8, a second latch 274 may include a latching projection (e.g., a second latching projection 276) that may be configured to engage a second tab 200. A second latching projection 276 may extend, protrude, and/or project from a free/distal end of a second latch 274. A second latching projection 276 may include a projection surface (e.g., a second projection surface 278), which may be configured to engage, contact, and/or abut a second tab 200 (e.g., a third tab portion 206 of a second tab 200 and/or a tab surface 212 thereof). A second projection surface 278 may face generally away from a cover 120, toward a closed end 234 of the housing member 124, and/or generally downward in a Z-direction. A second latch 274 may include a second sliding surface 280, which may be configured to facilitate adjusting, elastically deforming, flexing, and/or deflecting of the second tab 200 (e.g., generally in a X-direction).

With embodiments, such as generally illustrated in FIG. 6A, a housing member 124 may include a second latch 274 and another/additional second latch 274′, which may be disposed at or about opposite ends of the second end 254 of the housing member 124 such that each of the second latches 274, 274′ are disposed at or about a corner of the electrical unit housing 102. A second latch 274′ may be configured to engage a second tab 200′ and/or may be configured in a similar and/or same manner as a second latch 274. A second latch 274′ may include a second latching projection 276′, a second projection surface 278′ and/or a second sliding surface 280′, which may be configured in a similar and/or same manner as the corresponding feature of a second latch 274.

An embodiment of a method of assembling at least a portion of an electrical unit housing 102 is generally illustrated in FIGS. 9A-10D. As generally shown in FIG. 9A, the method may include disposing a cover 120 above an open end 236 of a housing member 124, such as generally in a Z-direction. Disposing a cover 120 may include aligning one or more first latches 170, 170′ with a corresponding first tab 260, 260′ relative to a Z-direction and/or aligning one or more second latches 274, 274′ with a corresponding second tab 200, 200′ relative to a Z-direction. Once the latches 170, 170′ 274, 274′ and tabs 200, 200′, 260, 260′ are aligned, the cover 120 may be moved and/or adjusted (e.g., linearly, straight down, etc.) onto the open end 236 of the housing member 124 in an assembly direction, which may extend substantially parallel to a Z-direction (e.g., downward). The cover 120 (e.g., an open end 152) may then be pressed toward, onto, and/or against the open end 236 of the housing member 124 in the assembly direction (e.g., generally in a Z-direction) to engage one or more first latches 170, 170′ with the corresponding first tab 260, 260′ and/or one or more second latches 274, 274′ with the corresponding second tab 200, 200′, which may cause the cover 120 and the housing member 124 to be releasably connected together via one or more first connectors 128, 128′ and/or one or more second connectors 130, 130′ as generally illustrated in FIG. 9B. Engaging a first latch 170, 170′ with a first tab 260, 260′ may include one or more processes and/or steps, such as those generally illustrated in FIGS. 10A-10D, which are described in detail below. Engaging a second latch 274, 274′ with a second tab 200, 200′ may include one or more processes and/or steps, which are described further below.

With embodiments, such as generally illustrated in FIG. 9A, pressing the cover 120 onto the housing member 124 may include applying a force F (e.g., a singular force F) to the cover 120 in the assembly direction (e.g., generally in a Z-direction). Applying a force F to the cover 120 may include applying the force F to the formation 224 of the cover 120, such as to the main portion 226 of the formation 224. The method may include distributing at least a portion of the applied force F toward one or more first connectors 128, 128′ and/or one or more second connectors 130, 130′, which may cause the applied force F to be concentrated at or about the one or more connectors 128, 128′, 130, 130′, which may reduce a minimum amount of force F that needs to be applied to the cover 120 to engage one or more first latches 170, 170′ with the corresponding first tab 260, 260′ and/or one or more second latches 274, 274′ with the corresponding second tab 200, 200′, which may result in the cover 120 being easier to connect to the housing member 124. With some configurations, distributing the force F may facilitate and/or allow substantially simultaneous connection/engagement of a plurality of connectors, such as first and second connectors 128, 128′, 130, 130′ that may be disposed proximate respective corners/vertices of an electrical unit housing 102.

In embodiments, such as generally illustrated in FIG. 10A, moving the cover 120 onto the housing member 124 may include adjusting a first latch 170 to engage, contact, and/or abut the first tab 260, which may include adjusting the angled latch portion 184 and/or the first sliding surface 186 of the first latch 170 to engage, contact, and/or abut the first surface 262 of the first tab 260. Pressing the cover 120 onto the housing member 124 may include sliding the first latch 170 along the first surface 262 of the first tab 260 toward the second surface 264 (e.g., in a direction extending from the first end 262A of the first surface 262 to the second end 262B of the first surface 262). Sliding the first latch 170 along the first surface 262 toward the second surface 264 may include adjusting, elastically deforming, flexing, and/or deflecting the first latch 170, such as from an unengaged position (e.g., see FIG. 10A) toward and/or to a deflected position (see, e.g., FIG. 10B). Due to the configuration (e.g., the angle/inclination) of the first surface 262 of the first tab 260, the first latch 170 may be adjusted, elastically deformed, flexed, deflected, etc. away from a wall portion 240 of the housing member 124 to which the first tab 260 is connected (e.g., generally in an X-direction). When adjusting the first latch 170 toward the deflected position, the angled latch portion 184 and/or the first sliding surface 186 of the first latch 170 may be adjusted from a first position where it is disposed obliquely relative to the first surface 262 (e.g., when the first sliding surface 186 is initially brought into contact with the first surface 262) toward a second position in which it is disposed substantially parallel to and/or flush against the first surface 262. Sliding the first latch 170 along the first surface 262 may include moving the first latch 170 (e.g., an angled latch portion 184) from being in contact and/or abutment with the first surface 262 to the first latch 170 (e.g., the first latching projection 180 of the first latch 170) being in contact and/or abutment with the second surface 264 (see, e.g., FIG. 10B), such as by moving the first latch 170 from the second end 262B of the first surface 262 onto the first end 264A of the second surface 264, such as via continued application of force F.

In embodiments, such as generally illustrated in FIG. 10C, pressing the cover 120 onto the housing member 124 may, additionally and/or alternatively, include sliding the first latch 170 (e.g., the first latching projection 180) along the second surface 264 of the first tab 260 toward the third surface 266 (e.g., in a direction extending from the first end 264A of the second surface 264 to the second end 264B of the second surface 264). Sliding the first latch 170 along the second surface 264 toward the third surface 266 may include adjusting, elastically deforming, flexing, and/or deflecting the first latch 170, such as from a deflected position (e.g., see FIG. 10B) toward and/or to an engaged position (see, e.g., FIGS. 7 and 10D). The first latch 170 may be adjusted, elastically deformed, flexed, deflected, etc. toward a wall portion 240 of the housing member 124 to which the first tab 260 is connected (e.g., generally in an X-direction). Adjusting, elastically deforming, flexing, and/or deflecting the first latch 170 may include the first latch 170 (e.g., the first latching projection 180) contacting, pressing against, applying a force to, and/or being biasing against the second surface 264 of the first tab 260 (e.g., due to the first latch 170 being biased toward the unengaged position and/or the engaged position). A configuration (e.g., an inward angle/inclination) of the second surface 264 of the first tab 260 may facilitate sliding of the first latch 170 along the second surface 264 toward an engaged position (e.g., in inward angle may provide an inertia latch effect). This in turn may reduce an amount of force F (at least to some extent) applied to the cover 120 to engage the first latch 170 with the first tab 260 when pressing the cover 120 onto the housing member 124, which may in turn facilitate connecting the cover 120 and the housing member 124 together.

In some example embodiments, the first latch 170 may contact, press against, and/or be biased against the second surface 264 of the first tab 260 with sufficient force to slide the first latch 170 along the second surface 264 toward an engaged position such that a user need not press and/or apply any force F (or provide a lesser amount of force) to the cover 120 after the first latch 170 has been brought into contact and/or abutment with the second surface 264 of the first tab 260. Sliding the first latch 170 along the second surface 264 may include moving the first latch 170 (e.g., the first latching projection 180) from being in contact and/or abutment with the second surface 264 (see, e.g., FIG. 10C) to the first latch 170 (e.g., the first latching projection 180 and/or the third tab portion 206) being in contact and/or abutment with the third surface 266 (see, e.g., FIGS. 7 and 10D), such as by adjusting the first latch 170 from the second end 264B of the second surface 264 onto the first end 266A of the third surface 266. Adjusting the first latch 170 to contact the third surface 266 may include adjusting the first projection surface 182 of the first latch 170 to engage, contact, and/or abut the third surface 266 of the first tab 260 (e.g., adjusting the first latch 170 to the engaged position), which may cause the cover 120 and the housing member 124 to be releasably connected to one another. Additionally or alternatively, moving the first latch 170 to contact the third surface 266 may include adjusting, moving, inserting, etc. at least a portion of the first tab 260 into a latch opening 178 of the first latch 170 (see, e.g., FIG. 7). Engaging a first latch 170′ and a first tab 260′ may involve one or more of the steps described above with respect to engaging a first latch 170 and a first tab 260, and/or may occur and/or may be performed at substantially the same time as engaging the first latch 170 and the first tab 260.

In embodiments, such as generally illustrated in FIG. 10A, adjusting the cover 120 onto the housing member 124 may include adjusting a second tab 200 to engage, contact, and/or abut the second latch 274, which may include adjusting the third tab portion 206 of the second tab 200 to engage, contact, and/or abut a second sliding surface 280 of the second latch 274. Pressing the cover 120 onto the housing member 124 may include sliding the second tab 200 along the second sliding surface 280 of the second latch 274, which may adjust, elastically deform, flex, and/or deflect the second tab 200, such as from an unengaged position toward and/or to a deflected position. Due to the configuration (e.g., the angle/inclination) of the second sliding surface 280, the second tab 200 (e.g., the first tab portion 202 and/or the second tab portion 204 of the second tab 200) may be adjusted, elastically deformed, flexed, deflected, etc. toward a wall portion 156 of the cover 120 to which the second tab 200 may be connected (e.g., generally in an X-direction). Sliding the second tab 200 along the second sliding surface 280 of the second latch 274 may include adjusting the second tab 200 (e.g., the third tab portion 206) from being in contact and/or abutment with the second sliding surface 280 to the second tab 200 (e.g., the tab surface 212 of the third tab portion 206) being in contact and/or abutment with the second projection surface 278 of the second latch 274 such that second tab 200 is adjusted, flexed, deflected, etc. from the deflected position to an engaged position (see, e.g., FIG. 10B), which may cause the cover 120 and the housing member 124 to be releasably connected to one another. Additionally or alternatively, moving the second tab 200 to contact the second projection surface 278 may include adjusting, moving, inserting, etc. at least a portion of the second latch 274 (e.g., the second latching projection 276) into a tab opening 210 of the second tab 200 (see, e.g., FIG. 8). Engaging a second tab 200′ and a second latch 274′ may involve one or more of the steps described above with respect to engaging a second tab 200 and a second latch 274, and/or may occur and/or may be performed at substantially the same time as engaging the second tab 200 and the second latch 274, which may, at least in some circumstances be performed at substantially the same time as engaging first tabs 260, 260′ with first latches 170, 170′.

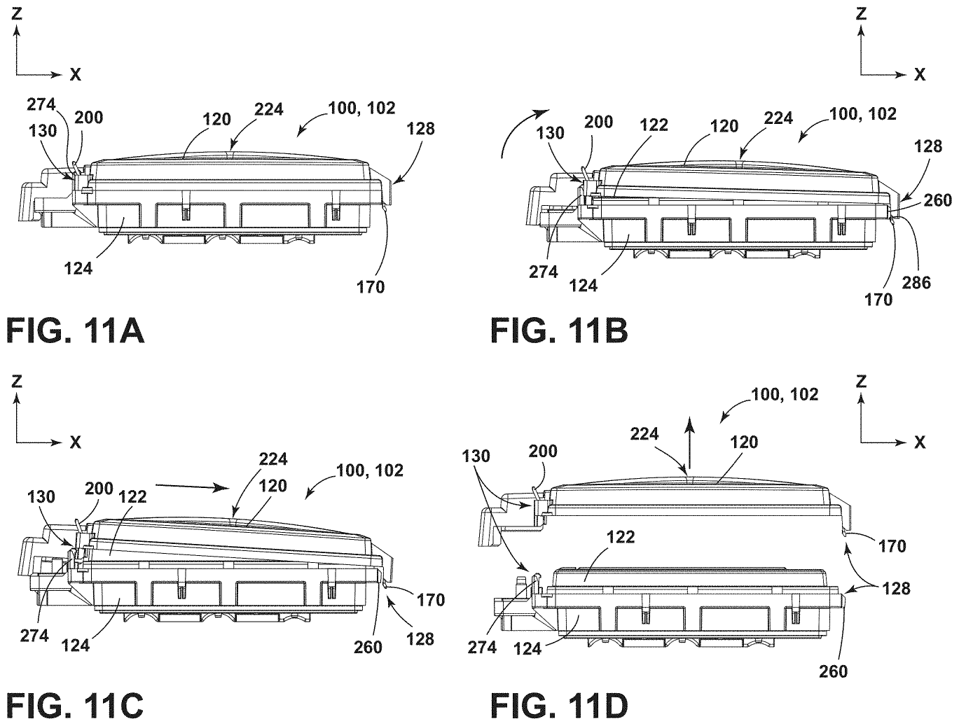

An embodiment of a method of disassembling at least a portion of an electrical unit 100 and/or electrical unit housing 102 is generally illustrated in FIGS. 11A-11D. The method may include adjusting, elastically deforming, flexing, and/or deflecting the second tab 200 to adjust the second tab 200 from an engaged position toward and/or to a deflected position, such as by a user pressing on and/or applying a force to a fourth tab portion 208 of the second tab 200 as generally shown in FIG. 11A. As generally shown in FIG. 11B, once the second tab 200 is in the deflected position, a second end 162 of the cover 120 may be adjusted, lifted, moved, etc. to rotate the cover 120 about a rotation axis 286, which may extend substantially parallel to a Y-direction. In at least some examples, the rotation axis 286 may be disposed at or about one or more first connectors 128, 128′. Additionally and/or alternatively, the rotation axis 286 may be defined by and/or extend substantially along a transition (e.g., an edge) at which the second surface 264 and the third surface 266 of the first tab 260 meet, contact, and/or abut one another. The cover 120 may be adjusted, lifted, moved, etc. until there is, at the second end 162 of the cover 120, a clearance between the open end 152 of the cover 120 and the second cover 122. As generally illustrated in FIG. 11C, the cover 120 may then be adjusted, moved, slid, etc. (e.g., generally in an X-direction) to disengage the first latch 170 and the first tab 260, which may include adjusting, moving, etc. the first latch 170 to no longer contact the first tab 260 and/or removing the first tab 260 from the latch opening 178 of the first latch 170. As generally illustrated in FIG. 11D, the cover 120 may be adjusted, moved, lifted, etc. (e.g., generally in a Z-direction) off of the housing member 124 after the first latch 170 and the first tab 260 have been disengaged to remove the cover 120 from the housing member 124. In at least some examples, all second tabs 200, 200′ may be (e.g., simultaneously) actuated and/or disengaged from the corresponding second latches 274, the cover 120 rotated (at least to some extent), and then all first latches 170 and first tabs 260 disengaged, prior to adjusting/moving the cover 120 off of the housing member 124.

While embodiments are generally illustrated with the cover 120 including first latches 170, 170′ and the second tabs 200, 200′ and the housing member 124 including second latches 274, 274′ and first tabs 260, 260′, embodiments may also include the opposite configuration or a combination/mixture of tab/latch configurations.

Various examples/embodiments are described herein for various apparatuses, systems, and/or methods. Numerous specific details are set forth to provide a thorough understanding of the overall structure, function, manufacture, and use of the examples/embodiments as described in the specification and illustrated in the accompanying drawings. It will be understood by those skilled in the art, however, that the examples/embodiments may be practiced without such specific details. In other instances, well-known operations, components, and elements have not been described in detail so as not to obscure the examples/embodiments described in the specification. Those of ordinary skill in the art will understand that the examples/embodiments described and illustrated herein are non-limiting examples, and thus it can be appreciated that the specific structural and functional details disclosed herein may be representative and do not necessarily limit the scope of the embodiments.

Reference throughout the specification to “examples, “in examples,” “with examples,” “various embodiments,” “with embodiments,” “in embodiments,” or “an embodiment,” or the like, means that a particular feature, structure, or characteristic described in connection with the example/embodiment is included in at least one embodiment. Thus, appearances of the phrases “examples, “in examples,” “with examples,” “in various embodiments,” “with embodiments,” “in embodiments,” or “an embodiment,” or the like, in places throughout the specification are not necessarily all referring to the same embodiment. Furthermore, the particular features, structures, or characteristics may be combined in any suitable manner in one or more examples/embodiments. Thus, the particular features, structures, or characteristics illustrated or described in connection with one embodiment/example may be combined, in whole or in part, with the features, structures, functions, and/or characteristics of one or more other embodiments/examples without limitation given that such combination is not illogical or non-functional. Moreover, many modifications may be made to adapt a particular situation or material to the teachings of the present disclosure without departing from the scope thereof.

It should be understood that references to a single element are not necessarily so limited and may include one or more of such element. Any directional references (e.g., plus, minus, upper, lower, upward, downward, left, right, leftward, rightward, top, bottom, above, below, vertical, horizontal, clockwise, and counterclockwise) are only used for identification purposes to aid the reader's understanding of the present disclosure, and do not create limitations, particularly as to the position, orientation, or use of examples/embodiments.

Joinder references (e.g., attached, coupled, connected, and the like) are to be construed broadly and may include intermediate members between a connection of elements, relative movement between elements, direct connections, indirect connections, fixed connections, movable connections, operative connections, indirect contact, and/or direct contact. As such, joinder references do not necessarily imply that two elements are directly connected/coupled and in fixed relation to each other. Connections of electrical components, if any, may include mechanical connections, electrical connections, wired connections, and/or wireless connections, among others. The use of “e.g.” in the specification is to be construed broadly and is used to provide non-limiting examples of embodiments of the disclosure, and the disclosure is not limited to such examples. Uses of “and” and “or” are to be construed broadly (e.g., to be treated as “and/or”). For example and without limitation, uses of “and” do not necessarily require all elements or features listed, and uses of “or” are inclusive unless such a construction would be illogical.

While processes, systems, and methods may be described herein in connection with one or more steps in a particular sequence, it should be understood that such methods may be practiced with the steps in a different order, with certain steps performed simultaneously, with additional steps, and/or with certain described steps omitted.

All matter contained in the above description or shown in the accompanying drawings shall be interpreted as illustrative only and not limiting. Changes in detail or structure may be made without departing from the present disclosure.

What is claimed is:

1. An electrical unit housing, comprising:
a housing member;
a cover releasably connectable to the housing member in an assembly direction; and
a connector including a latch and a tab, the latch disposed on the cover and the tab disposed on the housing member;
the tab including a first surface, a second surface, and a third surface that extend obliquely or perpendicularly relative to each other;
wherein the second surface extends from the first surface to the third surface;
wherein the second surface connects the first surface to the third surface;
wherein the latch is biased toward contact with the tab; and
wherein the second surface is configured to facilitate a movement of the latch toward an engaged position.

2. The electrical unit housing of claim 1, wherein:
the cover is releasably connectable to the housing member via applying a force to the cover to (i) slide the latch along the first surface, (ii) flex the latch from an unengaged position toward a deflected position as the latch slides along the first surface, and (iii) dispose the latch in contact with the second surface of the tab after the latch slides beyond an end of the first surface; and
wherein the second surface is configured to bias the latch, at least to some extent, in the assembly direction.

3. The electrical unit housing of claim 1, wherein:
the latch includes a latching projection protruding therefrom; and
when the latch is in the engaged position, the latching projection is engaged with the third surface of the tab connecting the housing member and the cover to one another.

4. The electrical unit housing of claim 1, wherein:
a first end of the first surface contacts the housing member;
a second end of the first surface contacts a first end of the second surface;
a second end of the second surface contacts a first end of the third surface; and
a second end of the third surface contacts the housing member.

5. The electrical unit housing of claim 4, wherein, relative to the assembly direction, the first end of the third surface is disposed farther from the first end of the first surface than the second end of the third surface.

6. The electrical unit housing of claim 4, wherein the first surface extends farther from the housing member than the third surface.

7. The electrical unit housing of claim 1, wherein the latch includes a latch opening configured to receive at least a portion of the tab when in the engaged position.

8. The electrical unit housing of claim 1, wherein:
the latch includes a first latch portion, a second latch portion, a third latch portion, and an angled latch portion;
the third latch portion extends between and connects the first latch portion and the second latch portion; and
the angled latch portion protrudes from the third latch portion and is disposed obliquely and/or perpendicularly relative to the first latch portion, the second latch portion, the third latch portion.

9. The electrical unit housing of claim 8, wherein:
the cover is releasably connectable to the housing member via applying a force to the cover to (i) slide the latch along the first surface, (ii) flex the latch from an unengaged position toward a deflected position as the latch slides along the first surface, and (iii) dispose the latch in contact with the second surface of the tab after the latch slides beyond an end of the first surface;
when the latch is in the unengaged position, the angled latch portion is disposed obliquely to the first surface; and
the angled latch portion is disposed substantially parallel to the first surface, at least temporarily, when the latch slides along the first surface.

10. The electrical unit housing of claim 8, wherein the latch includes a latching projection that protrudes from the third latch portion and is configured to contact the third surface.

11. The electrical unit housing of claim 1, wherein the cover includes a formation configured to distribute at least a portion of a force applied to the cover toward the connector.

12. The electrical unit housing of claim 11, wherein:
the connector includes a plurality of connectors; and
the formation has a hub-and-spoke configuration.

13. The electrical unit housing of claim 11, including a plurality of connectors, the plurality of connectors including the connector;
wherein the formation includes a plurality of ribs; and
the formation includes a main portion from which the plurality of ribs protrude.

14. The electrical unit housing of claim 13, wherein:
the main portion is disposed at or about a center of a base portion of the cover; and
the plurality of ribs each extend from the main portion toward a respective connector of the plurality of connectors.

15. The electrical unit housing of claim 13, wherein a height of the formation relative to a base portion of the cover is greatest at the main portion and the height of the formation decreases in a direction extending away from the main portion.

16. The electrical unit housing of claim 1, including a second connector disposed opposite the connector, wherein the second connector includes a second latch and a second tab;
wherein the second tab is disposed on the cover; and
the second latch is disposed on the housing member.

17. The electrical unit housing of claim 16, wherein:
the second tab includes a first tab portion, a second tab portion, a third tab portion, and a fourth tab portion;
the fourth tab portion extends between and connects a free end of the first tab portion and a free end of the second tab portion; and
the third tab portion extends between and connects the first tab portion and the second tab portion and is spaced apart from the fourth tab portion.

18. The electrical unit housing of claim 17, wherein:
the fourth tab portion is actuatable via a user;
the third tab portion is configured to engage the second latch;
the first tab portion and the second tab portion are configured to move to adjust the third tab portion away from the second latch when the fourth tab portion is actuated; and
the connector is configured such that, after the second tab has been actuated and is disengaged from the second latch, the cover is pivotable about a rotation axis disposed in a region of the connector to disengage the latch from the tab.

19. An electrical unit housing, comprising:
a housing member;
a cover releasably connectable to the housing member; and
a plurality of connectors via which the housing member and the cover are releasably connected to one another;
wherein the cover includes a formation configured to distribute at least a portion of a pressing force applied to the cover toward the plurality of connectors to facilitate connecting the cover and the housing member to one another.

20. An electrical unit housing, comprising:
a housing member;
a plurality of connectors; and
a cover including a formation configured to distribute at least a portion of a force applied to the cover toward the plurality of connectors;
wherein the plurality of connectors include:
a latch extending from the cover substantially in an assembly direction; and
a tab protruding laterally from the housing member, the tab including a first surface, a second surface, and a third surface that extend obliquely or perpendicularly relative to one another;
wherein the cover is releasably connectable to the housing member via applying the force to the cover to (i) slide the latch along the first surface, (ii) flex the latch from an unengaged position toward a deflected position as the latch slides along the first surface, and (iii) dispose the latch in contact with the second surface after the latch slides beyond an end of the first surface;
wherein the second surface is configured to bias the latch, at least to some extent, in the assembly direction; and
wherein, when the latch is in an engaged position, the latch is in contact with the third surface.
